(19) United States
(12) Patent Application Publication
(10) Pub. No.: US 2025/0051916 A1
(43) Pub. Date: Feb. 13, 2025

(54) HIGH-PRESSURE SUBSTRATE PROCESSING APPARATUS AND HIGH-PRESSURE CHEMICAL VAPOR DEPOSITION METHOD FOR SUBSTRATE USING SAME

(71) Applicant: HPSP Co., Ltd., Hwaseong-si (KR)

(72) Inventor: Sung Kil CHO, Suwon-si (KR)

(21) Appl. No.: 18/913,139

(22) Filed: Oct. 11, 2024

Related U.S. Application Data
(63) Continuation of application No. PCT/KR2023/004022, filed on Mar. 27, 2023.

(30) Foreign Application Priority Data
Apr. 12, 2022 (KR) 10-2022-0044890
May 30, 2022 (KR) 10-2022-0066002

(51) Int. Cl. C23C 16/455; C23C 16/44; H01L 21/02

(52) U.S. Cl. CPC C23C 16/45557; C23C 16/4412; H01L 21/02271

(57) ABSTRACT

The present disclosure provides a high-pressure substrate processing apparatus and a high-pressure chemical vapor deposition method for a substrate, using same, the high-pressure substrate processing apparatus comprising: a chamber having an inner space in which a substrate to be processed is accommodated; a fluid supply module which communicates with the inner space and is configured to supply a fluid to the substrate to be processed; and a first exhaust module and a second exhaust module which communicate with the inner space and are configured to exhaust the fluid through different paths, wherein the adjustment amount of the first exhaust module for the pressure in the inner space is smaller than the adjustment amount of the second exhaust module, and the first exhaust module operates only when the inner space is in a high pressure higher than atmospheric pressure.

### TECHNICAL FIELD

The present disclosure relates to a high-pressure substrate processing apparatus for semiconductor manufacturing and a high-pressure chemical vapor deposition method for a substrate using the same.

### BACKGROUND ART

In general, a semiconductor manufacturing process is largely divided into a pre-process and a post-process. The pre-process includes processes such as oxidation, deposition, exposure, etching, ion implantation, wiring, etc.

The deposition process is a process of depositing a very thin layer of a desired material on a surface of a wafer. Specific deposition methods include chemical vapor deposition (CVD), physical vapor deposition (PVD), atomic layer deposition (ALD), etc. The chemical vapor deposition forms a thin film through a chemical reaction, and the physical vapor deposition forms a thin film using a physical method. The atomic layer deposition forms a very thin film using a method of stacking atomic layers.

The chemical vapor deposition or the atomic layer deposition has a high thermal budget when forming a film at low pressure, so its range of use is extremely limited. In complex circuit patterns with a large aspect ratio, step coverage becomes poor. The poor step coverage is a factor that reduces the productivity of semiconductor devices.

### DISCLOSURE

### Technical Problem

An object of the present disclosure provides a high-pressure substrate processing apparatus capable of improving the quality of a deposition film and increasing the productivity of a semiconductor device, and a high-pressure chemical vapor deposition method for a substrate using the same.

### Technical Solution

In one general aspect, a high-pressure substrate processing apparatus includes: a chamber having an inner space in which a substrate to be processed is accommodated; a fluid supply module configured to communicate with the inner space to supply a fluid to the substrate to be processed; and a first exhaust module and a second exhaust module configured to communicate with the inner space to exhaust the fluid through different paths, in which an adjustment amount of the first exhaust module for pressure in the inner space is smaller than that of the second exhaust module, and the first exhaust module operates only when the inner space is in a high pressure higher than atmospheric pressure.

Only the second exhaust module may operate except for the first exhaust module when the inner space is in a low pressure lower than the atmospheric pressure, and the second exhaust module selectively operate when the inner space is in the high pressure during a transition process from the high pressure to the low pressure.

The first exhaust module may include a first exhaust line, and the second exhaust module may include a second exhaust line having a larger flow cross-sectional area than the first exhaust line.

A diameter of the second exhaust line may be 5 to 10 times larger than that of the first exhaust line.

The first exhaust module may further include a first pressure regulating valve installed in the first exhaust line, and the second exhaust module may include a second pressure regulating valve that is installed in the second exhaust line and has a pressure adjustment range greater than that of the first pressure regulating valve.

The first pressure regulating valve may include a needle valve, and the second pressure regulating valve may include a throttle valve.

The second exhaust module may further include vacuum pump that is installed in the second exhaust line, and the vacuum pump may operate when the pressure is the low pressure and selectively operate when the pressure is the high pressure.

In another general aspect, a high-pressure chemical vapor deposition method for a substrate includes: loading a substrate to be processed into an inner space of a chamber; supplying a fluid containing deposition gas to the inner space so that a pressure of the inner space becomes a high pressure higher than atmospheric pressure; and exhausting the fluid through a first exhaust module having a relatively small adjustment amount while a second exhaust module having a relatively large adjustment amount for the pressure of the inner space being closed and finely adjusting the pressure of the high pressure so that the deposition gas flows toward the substrate to be processed and is deposited on the substrate to be processed.

The high pressure may be a pressure determined within a range of 10 ATM to 40 ATM in order to improve film quality of a deposition film deposited on the substrate to be processed.

The high-pressure chemical vapor deposition method may further include maintaining a temperature of the substrate to be processed at a temperature determined within a range of 500° C. to 1,000° C.

The deposition gas may contain: a source gas which is at least one of silane (SiH₄), disilane (Si₂H₆), or dichlorosilane (SiH₂Cl₂); and a reaction gas which is at least one of ammonia (NH₃), oxygen (O₂), nitrous oxide (N₂O), or ozone (O₃).

The high-pressure chemical vapor deposition method may further include, after the deposition on the substrate to be processed is completed, exhausting the fluid through the first exhaust module and the second exhaust module so that the pressure of the inner space reaches a low pressure lower than the atmospheric pressure.

After the deposition on the substrate to be processed is completed, the exhausting of the fluid through the first exhaust module and the second exhaust module so that the pressure of the inner space reaches a low pressure lower than the atmospheric pressure may include operating the first exhaust module at the high pressure, and stopping the operation of the first exhaust module and operating the second exhaust module at the low pressure.

After the deposition on the substrate to be processed is completed, the exhausting of the fluid through the first exhaust module and the second exhaust module so that the pressure of the inner space reaches a low pressure lower than the atmospheric pressure may include operating the first exhaust module in a first section of the high pressure, and stopping an operation of the first exhaust module and operating the second exhaust module in a second section of the high pressure and the low pressure.

When the second exhaust module operates in the second section, a vacuum pump of the second exhaust module may operate.

### Advantageous Effects

According to a high-pressure substrate processing apparatus and a high-pressure chemical vapor deposition method for a substrate using the same according to the present disclosure configured as described above, a fluid supplied by a fluid supply module to an inner space of a chamber accommodating a substrate to be processed is exhausted from the inner space by a first exhaust module and a second exhaust module, an adjustment amount of the first exhaust module with respect to the pressure of the inner space is smaller than that of the second exhaust module, and the first exhaust module operates only when the inner space is at high pressure higher than atmospheric pressure, thereby stably performing the deposition on the substrate even at high pressure. The high-pressure deposition provides advantages such as providing improved step coverage on a deposition film, thereby increasing the productivity of semiconductor devices.

### BRIEF DESCRIPTION OF THE DRAWINGS

FIG. 1 is a cross-sectional view illustrating a structure of a high-pressure substrate processing apparatus 100 according to an embodiment of the present disclosure.

FIG. 2 is a cross-sectional view illustrating that the high-pressure substrate processing apparatus 100 of FIG. 1 performs high-pressure deposition.

FIG. 3 is a cross-sectional view illustrating that the high-pressure substrate processing apparatus 100 of FIG. 1 exhausts the inner space 115 after deposition.

FIG. 4 is a block diagram illustrating a control configuration of the high-pressure substrate processing apparatus 100 of FIG. 1.

FIG. 5 is a flowchart illustrating a high-pressure chemical vapor deposition method for a substrate according to another embodiment of the present disclosure.

FIG. 6 is a flowchart illustrating in detail some steps (S3 and S5) of FIG. 5.

FIG. 7 is a flowchart illustrating in detail some steps (S7) of FIG. 5.

FIG. 8 is a cross-sectional view illustrating a semiconductor device O having a deposition film D₂ formed according to the high-pressure chemical vapor deposition method for a substrate of FIG. 5.

FIG. 9 is a graph illustrating experimental results for step coverage of the deposition film D₂ of the semiconductor device O of FIG. 8.

FIG. 10 is a graph illustrating experimental results for a deposition rate of the deposition film D₂ of the semiconductor device O of FIG. 8.

### BEST MODE

Hereinafter, exemplary embodiments of the present disclosure will be described in detail with reference to the accompanying drawings.

However, the present disclosure is not limited to embodiments set forth herein, but may be modified variously and implemented in various different forms. However, the embodiment is provided to ensure that the disclosure of the present disclosure is complete and to fully inform those skilled in the art of the scope of the invention. Therefore, the present disclosure is not limited to the embodiments disclosed below, but it should be understood that substitution or addition of components of one embodiment and components of another embodiment include all changes, equivalents, and substitutions included in the technical spirit and scope of the present disclosure.

It should be understood that the accompanying drawings are provided only in order to allow exemplary embodiments of the present disclosure to be easily understood, and the spirit of the present disclosure is not limited by the accompanying drawings, but includes all the modifications, equivalents, and substitutions included in the spirit and the scope of the present disclosure. In the drawings, components may be expressed exaggeratedly large or small in size or thickness for convenience of understanding, etc., but the scope of protection of the present disclosure should not be construed as limited.

Terms used in the present specification are used only in order to describe specific implementation examples or embodiments rather than limiting the present disclosure. Singular forms are intended to include plural forms unless the context clearly indicates otherwise. In the specification, terms such as ˜include, ˜consist of, etc., are intended to designate the existence of features, numbers, steps, operations, components, parts, or a combination thereof described in the specification. Also, it should be understood that terms such as “˜include” and “˜consist of” do not preclude the existence or addition possibility of one or more other features or numbers, steps, operations, components, parts, or combinations thereof.

The terms including ordinal numbers such as ‘first’ and ‘second’ may be used to describe various components, but these components are not limited by these terms. The terms are used to distinguish one component from another component.

It is to be understood that when one component is referred to as being “connected to” or “coupled to” another component, one component may be connected directly to or coupled directly to another component or be connected to or coupled to another component with the other component interposed therebetween. On the other hand, it is to be understood that when one component is referred to as being “connected directly to” or “coupled directly to” another component, it may be connected to or coupled to another component without the other component interposed therebetween.

When a component is referred to as being “on top” or “below” another component, it should be understood that not only is it disposed directly on top of other components, but there may also be other components in between.

Unless indicated otherwise, it is to be understood that all the terms used in the specification including technical and scientific terms have the same meaning as those that are generally understood by those who skilled in the art. It should be understood that the terms defined by the dictionary are identical with the meanings within the context of the related art, and they should not be ideally or excessively formally defined unless the context clearly dictates otherwise.

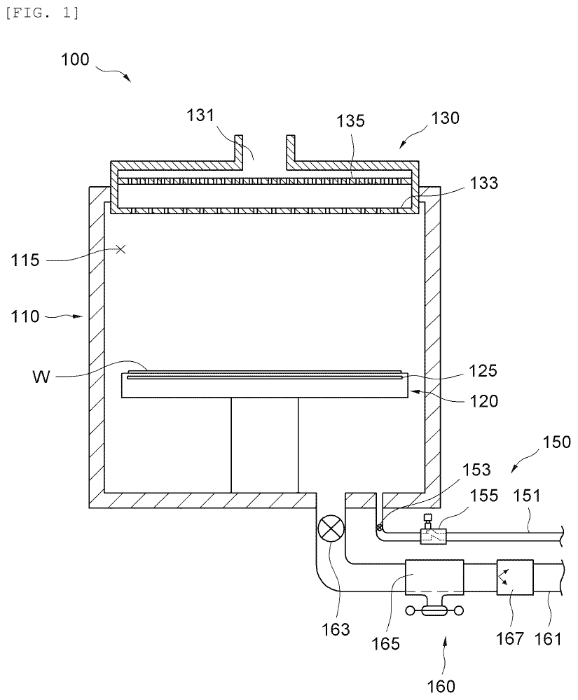

FIG. 1 is a cross-sectional view illustrating a structure of a high-pressure substrate processing apparatus 100 according to an embodiment of the present disclosure. Hereinafter, as the high-pressure substrate processing apparatus 100, a single wafer type processing apparatus is illustrated, but the present disclosure is not limited thereto, and a batch type processing apparatus may be applied.

Referring to FIG. 1, the high-pressure substrate processing apparatus 100 may include a chamber 110, a fluid supply module 130, a first exhaust module 150, and a second exhaust module 160.

The chamber 110 is a hollow structure having an inner space 115. A substrate W is accommodated in the inner space 115. The substrate W is generally a wafer, but is not limited thereto. The substrate W may be mounted in the inner space 115, specifically, on a support module 120. The support module 120 may be formed to support the substrate W at a position higher than the bottom of the inner space 115. The support module 120 may have a temperature unit 125 to control a temperature of the substrate W. The temperature unit 125 may be located at a lower side of the substrate W. The temperature unit 125 may include a heater for increasing the temperature of the substrate W, or a cooler for decreasing the temperature of the substrate W.

The fluid supply module 130 is configured to communicate with the inner space 115 to supply a fluid to the inner space 115. The fluid mainly refers to gas, but is not limited thereto. The fluid supply module 130 may specifically include a supply pipe 131, a distributor 133, and a regulator 135. The supply pipe 131 communicated with a fluid tank (not illustrated) and is supplied with a fluid therefrom. The distributor 133 communicates with the supply pipe 131 and is located on an upper side of the inner space 115. The distributor 133 evenly sprays the fluid received from the supply pipe 131 onto an area corresponding to the substrate W. The regulator 135 regulates the pressure of the fluid input from the supply pipe 131 and provides the fluid to the distributor 133. In an embodiment, a nozzle of regulator 135 may be formed more than that of distributor 133. Alternatively, a diameter of the nozzle of the regulator 135 may be different from that of the nozzle of the distributor 133.

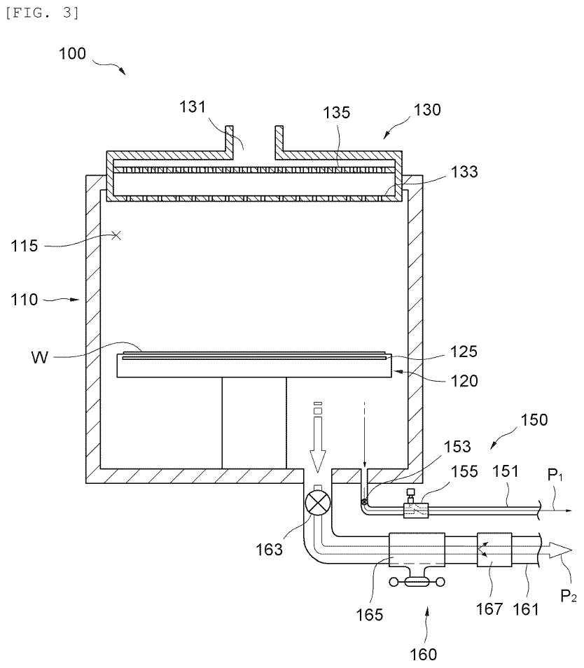

The first exhaust module 150 and the second exhaust module 160 are configured to communicate with the inner space 115 to exhaust the fluid of the inner space 115. The first exhaust module 150 and the second exhaust module 160 communicate with the inner space 115 through the bottom of the chamber 110 facing the fluid supply module 130. The first exhaust module 150 and the second exhaust module 160 also form exhaust paths P₁ and P₂ (see FIG. 3) having different characteristics.

Specifically, a first exhaust line 151 of the first exhaust module 150 and a second exhaust line 161 of the second exhaust module 160 have different flow cross-sectional areas. The second exhaust line 161 has a larger flow cross-sectional area than the first exhaust line 151. For example, the flow cross-sectional area of the second exhaust line 161 may be 5 to 10 times larger than that of the first exhaust line 151.

A first shut-off valve 153 and a second shut-off valve 163 are installed in the first exhaust line 151 and the second exhaust line 161, respectively. These allow or block the exhaust of the fluid through the first exhaust line 151 or the second exhaust line 161 while being open or closed.

A first pressure regulating valve 155 or a second pressure regulating valve 165 is also installed in the first exhaust line 151 and the second exhaust line 161, respectively. The first pressure regulating valve 155 and the second pressure regulating valve 165 have different pressure adjustment ranges. Specifically, the pressure adjustment range of the first pressure regulating valve 155 is smaller than that of the second pressure regulating valve 165. For this purpose, a needle valve may be adopted as the first pressure regulating valve 155, and a throttle valve may be adopted as the second pressure regulating valve 165. The needle valve may finely adjust the pressure of the high-pressure fluid in the first exhaust line 151 having a small flow cross-sectional area. Here, the high pressure refers to a pressure higher than the atmospheric pressure (atmospheric pressure), and may range from several ATM to several tens of ATM, but is not limited thereto.

A vacuum pump 167 may also be installed in the second exhaust line 161. The vacuum pump 167 operates to make the pressure of the inner space 115 low pressure. Here, the low pressure refers to a pressure lower than the atmospheric pressure, and may range from, for example, up to 1 mTorr. The vacuum pump 167 may also operate even in some sections of the atmospheric pressure range to increase the exhaust speed of the fluid exhausted along the second exhaust line 161.

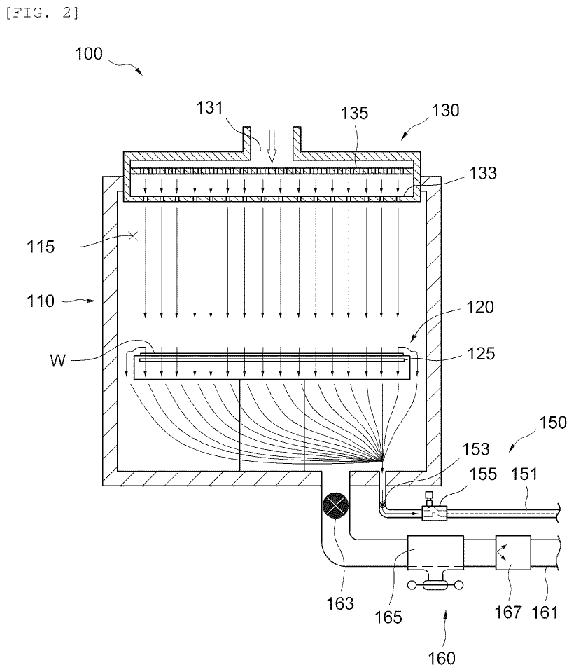

FIG. 2 is a cross-sectional view illustrating that the high-pressure substrate processing apparatus 100 of FIG. 1 performs high-pressure deposition.

Referring further to FIG. 2, in order to perform the high-pressure deposition on the substrate W, the fluid supply module 130 injects fluid into the inner space 115. The fluid should flow toward the substrate W and be deposited on the substrate W under high pressure conditions. In order to make the fluid flow, the fluid in the inner space 115 should be continuously exhausted to the outside.

To this end, the first exhaust module 150 operates while the second exhaust module 160 is in a non-operating state. In other words, the second shut-off valve 163 should be in a closed state, and the first shut-off valve 153 should be in an open state.

With the first shut-off valve 153 is in an open state, the first pressure regulating valve 155 operates to maintain the set pressure in the inner space 115 within the set high pressure, for example, a range of several ATM to several tens of ATM. The first pressure regulating valve 155 finely adjusts the pressure in the inner space 115 by increasing or decreasing the opening of the valve. It is difficult for the second pressure regulating valve 165 to perform the fine pressure adjustment at high pressure.

FIG. 3 is a cross-sectional view illustrating that the high-pressure substrate processing apparatus 100 of FIG. 1 exhausts the inner space 115 after deposition.

Referring to FIG. 3, the fluid in the inner space 115 needs to be exhausted entirely after the high-pressure deposition is completed. The entire exhaust should be performed to unload the deposited substrate W and load a new substrate. Only when byproducts from the deposition process are completely discharged, there is no problem in deposition on a new substrate.

For the entire exhaust, the first exhaust module 150 and the second exhaust module 160 are used together. For example, the first exhaust module 150 may operate first, and then the second exhaust module 160 may operate at a specific pressure.

Specifically, the first exhaust module 150 operates at high pressure, but does not operate at low pressure. The first exhaust module 150 may operate only at a specific high pressure close to atmospheric pressure, for example, up to 2 ATM. The second exhaust module 160 operates at low pressure. The second exhaust module 160 may operate from the specific high pressure above, or, alternatively, may not operate at all at the high pressure. In the case where the second exhaust module 160 operates from the specific high pressure, the first exhaust module 150 may not operate even in some sections of the high pressure. In the above, the high pressure may be divided into two sections. For example, a pressure section from several tens of ATM to 2 ATM may be referred to as the first section, and the remaining pressure section among the high pressure sections may be referred to as a second section. A reference pressure dividing the first section and the second section is presented as 2 ATM, but is not limited thereto. For example, the reference pressure may be 3 ATM or 1.5 ATM.

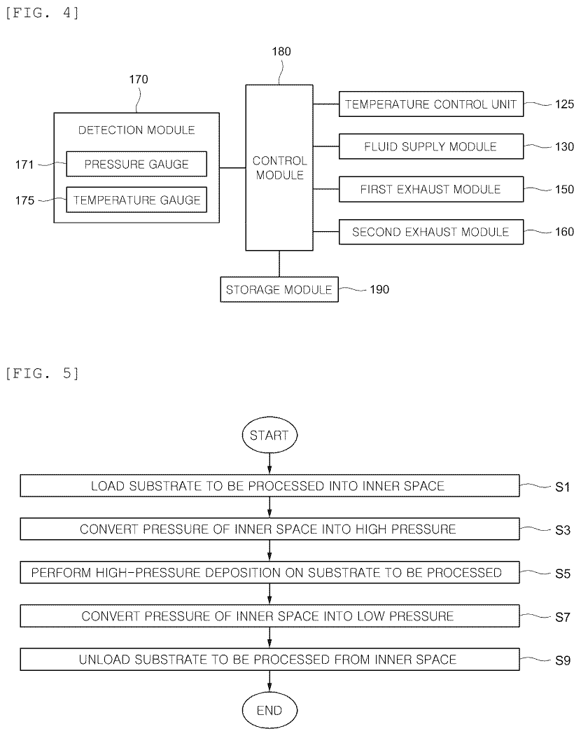

FIG. 4 is a block diagram illustrating a control configuration of the high-pressure substrate processing apparatus 100 of FIG. 1.

Referring to FIG. 4, the high-pressure substrate processing apparatus 100 may include a detection module 170, a control module 180, and a storage module 190, in addition to the temperature control unit 125 described above.

The detection module 170 is configured to detect the environment of the chamber 110, specifically, the inner space 115. The detection module 170 may be provided with a pressure gauge 171 and a temperature gauge 175. When the pressure gauge 171 detects the pressure of the inner space 115, the temperature gauge 175 detects the temperature of the substrate W.

The control module 180 is configured to control the temperature control unit 125, the fluid supply module 130, etc. The control module 180 may control the temperature control unit 125, etc., based on the detection result of the detection module 170.

The storage module 190 is configured to store data, programs, etc., that the control module 180 may refer to for control. The storage module 190 may include at least one type of storage medium among flash memory, hard disk, magnetic disk, and optical disk.

According to this configuration, the control module 180 controls the temperature control unit 125, etc., to perform the high-pressure chemical vapor deposition method for a substrate according to an embodiment of the present disclosure.

Specifically, the control module 180 controls the operation of the fluid supply module 130, the first exhaust module 150, and the second exhaust module 160 based on the pressure of the inner space 115 obtained through the pressure gauge 171. Accordingly, the pressure of the inner space 115 may be adjusted to the set high pressure or low pressure.

The control module 180 also controls the operation of the temperature control unit 125 based on the temperature of the substrate W obtained through the temperature gauge 175. According to the operation of the temperature control unit 125, the substrate W may be heated to reach the process temperature or cooled to reach the waiting temperature.

The specific details of the high-pressure chemical vapor deposition method according to the control of the control module 180 are described with reference to FIGS. 5 to 10.

FIG. 5 is a flowchart illustrating a high-pressure chemical vapor deposition method for a substrate according to another embodiment of the present disclosure.

Referring to FIG. 5 (and FIGS. 1 to 4), the control module 180 first loads the substrate to be processed W into the inner space 115 (S1). When loading the substrate W, the inner space 115 may be in the low-pressure state. The substrate W may be loaded into the inner space 115 through a load lock chamber (not illustrated).

After the substrate W is loaded, the control module 180 controls the fluid supply module 130 to supply a fluid to the inner space 115 at high pressure (S3). The fluid includes a deposition gas. The deposition gas may include a silicon-based source gas and an oxygen or nitrogen-based reaction gas. The source gas may include silicillane (SiH₄), disilane (Si₂H₆), or dichlorosilane (SiH₂Cl₂). The reaction gas may include ammonia (NH₃), oxygen (O₂), nitrous oxide (N₂O), or ozone (O₃). The fluid may also include an atmosphere gas. The atmosphere gas increases the pressure of the inner space 115 to reach the set high-pressure condition. The atmosphere gas may be, for example, nitrogen (N₂), but is not limited thereto.

The deposition on the substrate to be processed W is performed at a high pressure (S5). To this end, the deposition gas may be supplied to the inner space 115 while the inner space 115 reaches the set high pressure by the atmosphere gas. The deposition gas flows toward the substrate W and reacts with the surface of the substrate W, and thus, is deposited on the substrate W. The above deposition gas is not necessarily supplied after the above atmosphere gas is supplied to the inner space 115, and may be supplied to the inner space 115 together with the above atmosphere gas.

After the deposition on the substrate W is performed, the pressure of the inner space 115 is switched to the low pressure (S7). The pressure switching to a low pressure is achieved through the operation of the first exhaust module 150 and the second exhaust module 160. As the exhaust is performed until the inner space 115 reaches the low-pressure state, byproducts generated during the deposition process may be completely discharged from the inner space 115. This may prevent the contamination of the substrate to be deposited next.

At the low pressure, the substrate W is unloaded from the inner space 115 (S9). The unloading of the substrate W may be performed through a load lock chamber (not shown) communicating with the inner space 115.

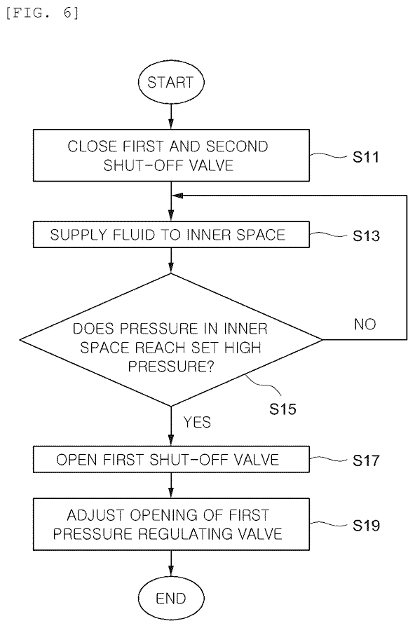

FIG. 6 is a flowchart illustrating in detail some steps (S3 and S5) of FIG. 5.

Referring further to FIG. 6, in order to supply the fluid to the inner space 115, the control module 180 first closes the first shut-off valve 153 and the second shut-off valve 163 (S11).

When the exhaust to the inner space 115 is blocked, the control module 180 controls the fluid supply module 130 to supply the fluid to the inner space 115 (S13). The atmospheric gas is preferentially supplied as the fluid, so that the pressure of the inner space 115 may increase.

The control module 180 detects the pressure of the inner space 115 through the pressure gauge 171. When the pressure of the inner space 115 reaches the set high pressure (S15), the fluid supply module 130 may supply the deposition gas.

The control module 180 opens the first shut-off valve 153 (S17). The second shut-off valve 163 is still closed. As the first shut-off valve 153 is open, the deposition gas flows toward the first exhaust line 151 through the substrate W.

The control module 180 adjusts the opening of the first pressure regulating valve 155 (S19). The control module 180 determines the opening of the first pressure regulating valve 155 based on the pressure detected by the pressure gauge 171. As the opening degree of the first pressure regulating valve 155 is adjusted, the pressure of the inner space 115 is finely adjusted. Accordingly, a flow rate of the deposition gas flowing toward the substrate W is also adjusted.

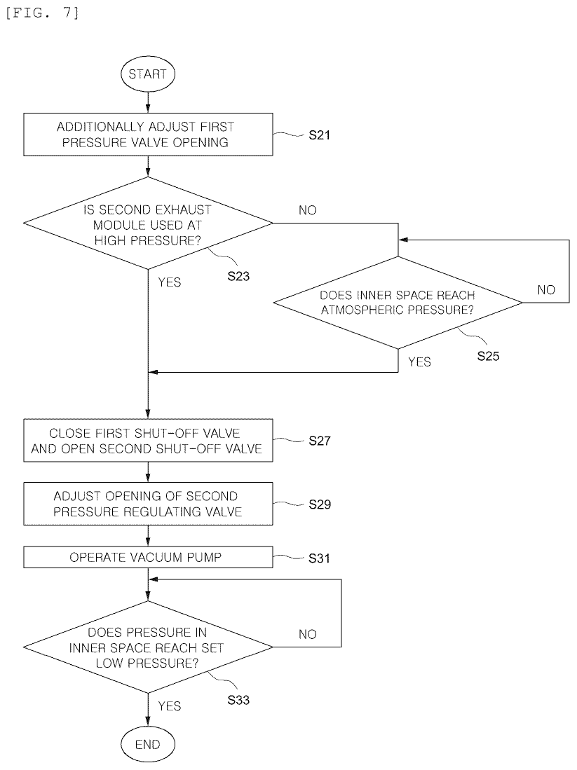

FIG. 7 is a flowchart illustrating in detail some steps (S7) of FIG. 5.

Referring further to FIG. 7, for exhaust at the high pressure, the control module 180 basically uses the first exhaust module 150. The first shut-off valve 153 remains in the previously opened state. The opening of the first pressure regulating valve 155 may be additionally adjusted (S21). In preparation for the case where the deposition gas flows toward the substrate W, the opening may be different when exhausting the fluid. By using the first exhaust module 150, the pressure of the inner space 115 may be lowered from several tens of ATM to the atmospheric pressure.

However, the second exhaust module 160 can be selectively utilized at a specific high pressure, for example, around 2 ATM (S23). Alternatively, it is also possible to lower the pressure to the atmospheric pressure only by the first exhaust module 150 (S25).

When the second exhaust module 160 is used in some high pressure sections, the first exhaust module 150 may no longer be used. For this purpose, the first shut-off valve 153 should be closed and the second shut-off valve 163 should be open (S27).

As the second shut-off valve 163 is open, the opening of the second pressure regulating valve 165 may be adjusted according to the pressure of the inner space 115 (S29).

The vacuum pump 167 also operates (S31). As the second exhaust module 160, specifically the vacuum pump 167, starts operating from the specific pressure of the high pressure, the rapid exhaust is possible in the pressure range from the specific pressure to the atmospheric pressure. This time reduction is particularly useful in a single wafer type processing device that processes wafers one by one.

When the pressure of the inner space 115 reaches the set low pressure, for example, 1 mTorr (S33), the control module 180 ends the switching operation to the low pressure (S7, see FIG. 5).

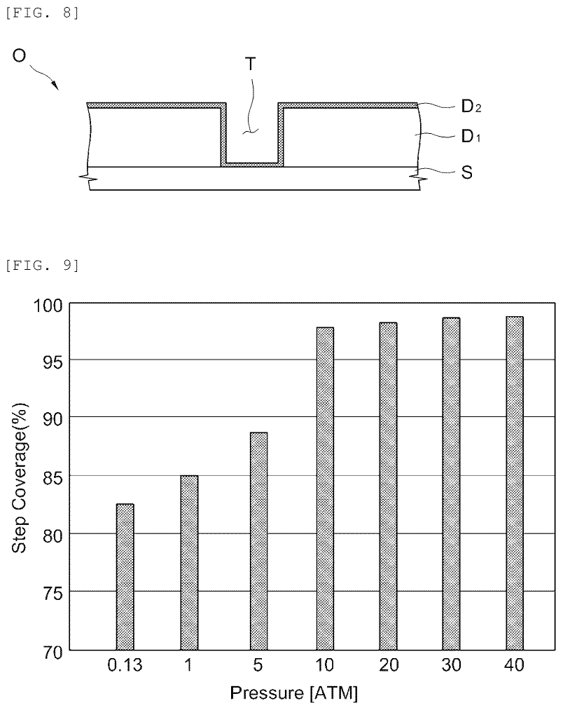

Hereinafter, the experimental results on the characteristics of the thin film deposited according to the high-pressure chemical vapor deposition method described above will be described with reference to FIGS. 8 to 10.

FIG. 8 is a cross-sectional view illustrating a semiconductor device O having a deposition film D₂ formed according to the high-pressure chemical vapor deposition method for a substrate of FIG. 5.

Referring to FIG. 8, in the semiconductor device O, a first deposition film D₁ is formed on a substrate S, and then a trench T is formed thereon. The first deposition film D₁ may be an oxide film or a nitride film.

The semiconductor device O is formed with a second deposition film D₂ according to the high-pressure chemical vapor deposition method described above. The second deposition film D₂ may also be an oxide film or a nitride film, and may be a different type of film from the first deposition film D₁.

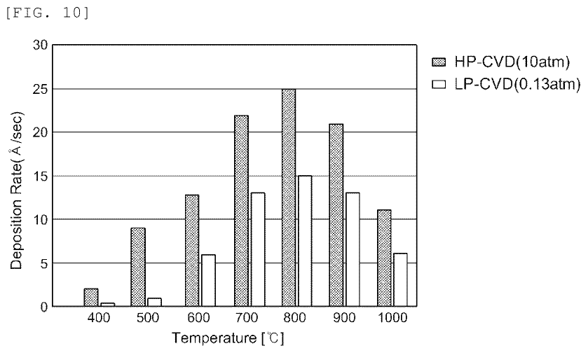

FIG. 9 is a graph illustrating experimental results for step coverage of the deposition film D₂ of the semiconductor device O of FIG. 8.

Referring further to FIG. 9, the film quality of the second deposition film D₂ of the semiconductor device O is affected by the set high pressure.

Specifically, the pressure of the inner space 115 was set within the range of 0.13 ATM to 40 ATM. The film quality of the second deposition film D₂ was evaluated from the perspective of step coverage.

When the pressure of the inner space 115 is 0.13 ATM, the step coverage is a level of 83%. At 1 ATM and 5 ATM, the step coverage reaches levels of 85% and 88%. Next, at 10 ATM, the step coverage reaches a level of 98% to 99%. As the pressure increases to 20 ATM, 30 ATM, and 40 ATM, the step coverage slightly increases.

Based on the results, the high pressure may be determined within a range of 10 ATM to 40 ATM in order to improve the film quality of the deposition film deposited on the substrate S to be processed. Furthermore, the high pressure may also be determined within the range of 10 ATM to 30 ATM. The maximum pressure is limited to 30 ATM in consideration of the fact that the step coverage reaches saturation at 30 ATM.

FIG. 10 is a graph illustrating experimental results for a deposition rate of the deposition film D₂ of the semiconductor device O of FIG. 8.

Referring further to FIG. 10, it can be confirmed that the deposition film D₂ formation efficiency is high when the vapor deposition is performed at 10 ATM compared to the vapor deposition at 0.13 ATM. The temperature of the substrate S was controlled within the range of 400° C. to 1,000° C., but it can be confirmed that the deposition efficiency of the high pressure deposition film D₂ is high at any temperature. In addition, it can be confirmed that the high pressure process at a relatively low temperature shows superior deposition performance compared to the low pressure process.

When the temperature of the substrate S is outside the range of 500° C. to 1,000° C., the gas decomposition and reaction rate of the silicon source and the reactant may be relatively significantly increased. This may cause the film quality uniformity of the deposition film D₂ to deteriorate and the film quality controllability to be lost, resulting in poor deposition quality despite the high-pressure conditions. For this reason, it is preferable that the temperature of the substrate S be determined within a range of 500° C. to 1,000° C. Furthermore, when the temperature of the substrate S approaches 1,000° C., the abnormal reaction is highly likely to occur. For this reason, the high-pressure deposition may be determined within a temperature range of 500° C. to 900° C.

### INDUSTRIAL APPLICABILITY

The present disclosure has industrial applicability in the field of manufacturing a high-pressure substrate processing apparatus and high-pressure chemical vapor deposition on a substrate.

1. A high-pressure substrate processing apparatus, comprising:
a chamber having an inner space in which a substrate to be processed is accommodated;
a fluid supply module configured to communicate with the inner space to supply a fluid to the substrate to be processed; and
a first exhaust module and a second exhaust module configured to communicate with the inner space to exhaust the fluid through different paths,
wherein an adjustment amount of the fluid in the first exhaust module for pressure in the inner space is smaller than that of the second exhaust module, and the first exhaust module operates only when the inner space is in a high pressure higher than atmospheric pressure.

2. The high-pressure substrate processing apparatus of claim 1, wherein only the second exhaust module operates except for the first exhaust module when the inner space is in a low pressure lower than the atmospheric pressure, and the second exhaust module selectively operates when the inner space is in the high pressure during a transition process from the high pressure to the low pressure.

3. The high-pressure substrate processing apparatus of claim 1, wherein the first exhaust module includes a first exhaust line, and
the second exhaust module includes a second exhaust line having a larger flow cross-sectional area than the first exhaust line.

4. The high-pressure substrate processing apparatus of claim 3, wherein a diameter of the second exhaust line is 5 to 10 times larger than that of the first exhaust line.

5. The high-pressure substrate processing apparatus of claim 3, wherein the first exhaust module further includes a first pressure regulating valve installed in the first exhaust line, and
the second exhaust module includes a second pressure regulating valve that is installed in the second exhaust line and has a pressure adjustment range greater than that of the first pressure regulating valve.

6. The high-pressure substrate processing apparatus of claim 5, wherein the first pressure regulating valve includes a needle valve, and
the second regulating valve includes a throttle valve.

7. The high-pressure substrate processing apparatus of claim 5, wherein the second exhaust module further includes a vacuum pump that is installed in the second exhaust line, and
the vacuum pump operates when the pressure is the low pressure and selectively operates when the pressure is the high pressure.

8. A high-pressure chemical vapor deposition method for a substrate, comprising:
loading a substrate to be processed into an inner space of a chamber;
supplying a fluid containing deposition gas to the inner space so that a pressure of the inner space becomes a high pressure higher than atmospheric pressure; and
exhausting the fluid through a first exhaust module having a relatively small adjustment amount while a second exhaust module having a relatively large adjustment amount for the pressure of the inner space being closed and finely adjusting the pressure of the high pressure so that the deposition gas flows toward the substrate to be processed and is deposited on the substrate to be processed.

9. The high-pressure chemical vapor deposition method of claim 8, wherein the high pressure is a pressure determined within a range of 10 ATM to 40 ATM in order to improve film quality of a deposition film deposited on the substrate to be processed.

10. The high-pressure chemical vapor deposition method of claim 8, further comprising maintaining a temperature of the substrate to be processed at a temperature determined within a range of 500° C. to 1,000° C.

11. The high-pressure chemical vapor deposition method of claim 8, wherein the deposition gas comprises:
a source gas which is at least one of silane (SiH₄), disilane (Si₂H₆), or dichlorosilane (SiH₂Cl₂); and
a reaction gas which is at least one of ammonia (NH₃), oxygen (O₂), nitrous oxide (N₂O), or ozone (O₃).

12. The high-pressure chemical vapor deposition method of claim 8, further comprising, after the deposition on the substrate to be processed is completed, exhausting the fluid through the first exhaust module and the second exhaust module so that the pressure of the inner space reaches a low pressure lower than the atmospheric pressure.

13. The high-pressure chemical vapor deposition method of claim 12, wherein after the deposition on the substrate to be processed is completed, the exhausting of the fluid through the first exhaust module and the second exhaust module so that the pressure of the inner space reaches a low pressure lower than the atmospheric pressure includes operating the first exhaust module at the high pressure, and stopping the operation of the first exhaust module and operating the second exhaust module at the low pressure.

14. The high-pressure chemical vapor deposition method of claim 12, wherein after the deposition on the substrate to be processed is completed, the exhausting of the fluid through the first exhaust module and the second exhaust module so that the pressure of the inner space reaches a low pressure lower than the atmospheric pressure includes operating the first exhaust module in a first section of the high pressure, and stopping an operation of the first exhaust module and operating the second exhaust module in a second section of the high pressure and the low pressure.

15. The high-pressure chemical vapor deposition method of claim 14, wherein when the second exhaust module operates in the second section, a vacuum pump of the second exhaust module operates.
